(19) United States
(12) Patent Application Publication
(10) Pub. No.: US 2006/0189013 A1
(43) Pub. Date: Aug. 24, 2006

(54) Method of making LED encapsulant with undulating surface

(75) Inventors: Craig R. Schardt, St. Paul, MN (US); David Scott Thompson, Woodbury, MN (US); Larry D. Boardman, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/064,686

(22) Filed: Feb. 24, 2005

(51) Int. Cl. H01L 21/56

(52) U.S. Cl. 438/26; 438/127

(57) ABSTRACT

An LED package includes an LED die and a light-transmissive material encapsulating the die. The encapsulant is formed by dispensing a curable material onto a substrate, such as a carrier on which is mounted the LED die, to form a liquid mass thereon, the liquid mass having an unconstrained smooth outer surface. The dispensed material is then cured to convert the liquid mass to a solid encapsulant having an outer encapsulant surface, the curing being performed under conditions to provide the outer encapsulant surface with undulating surface features. The encapsulant can alternatively be formed on a release liner or other film and after curing be affixed to an LED, such as an LED die, an LED die mounted to another substrate, or an LED die mounted to another substrate and encapsulated initially in another light transmissive material.

### FIELD OF THE INVENTION

The present invention relates to light emitting diode (LED) devices, components therefor, and related articles and processes.

### BACKGROUND

LEDs are a desirable choice of light source in part because of their relatively small size, low power/current requirements, rapid response time, long life, robust packaging, variety of available output wavelengths, and compatibility with modern circuit construction. These characteristics may help explain their widespread use over the past few decades in a multitude of different end use applications. Improvements to LEDs continue to be made in the areas of efficiency, brightness, and output wavelength, further enlarging the scope of potential end-use applications.

LEDs are typically sold in a packaged form that includes an LED die or chip mounted on a metal header. The header can have a reflective cup in which the LED die is mounted, and electrical leads connected to the LED die. Some packages also include a molded transparent resin that encapsulates the LED die. The encapsulating resin can have either a nominally hemispherical front surface to partially collimate light emitted from the die, or a nominally flat surface.

It is also known to provide the encapsulating material of an LED with certain types of irregular surfaces at the air/encapsulant interface. U.S. Patent Application Publication US 2003/0189217 (Imai), for example, provides a light scattering layer formed on an outermost layer of an LED sealant. Particles that project from the surface of the light scattering layer form protrusions and recesses, that roughen or undulate the surface to enhance light scattering action. Imai discloses forming the light scattering layer by printing with a paint that has the particles dispersed evenly therein, and then curing the printed layer. In another case, U.S. Patent Application Publication US 2003/0151361 (Ishizaka) discloses an LED with a resinous “cover” that seals a light emitting element and bonding wires, where a plurality of minute concave and convex portions are provided on a surface of the cover to promote light scattering. Ishizaka discloses that the concave and convex portions can be made by machining or etching the surface of the cover, by printing, by attaching a frosted glass to the cover, or by molding. In yet another case, U.S. Patent Application Publication US 2004/0084681 (Roberts) discloses a radiation emitter device that includes an LED and an encapsulant, where the encapsulant has a light exit surface defining a Fresnel lens comprising concentric circular grooves. Roberts discloses forming the lens by molding.

### BRIEF SUMMARY

The present application discloses, inter alia, packaged LED light sources that include an LED die and a light transmissive material that encapsulates the LED die. The light transmissive material, or encapsulant, which may consist essentially of a single layer or may comprise multiple layers, has an air interface defining an undulating surface. The undulating surface can include, for example, a plurality of surface features, such as protuberances and depressions, of non-uniform size and shape to promote light scattering out of the encapsulant.

A method is disclosed for forming the undulating surface that does not require etching, machining, or molding of the encapsulant. Instead, the method includes dispensing a curable material onto a substrate that may include, for example, an LED die mounted on a header. The dispensed curable material forms a liquid mass having an unconstrained smooth outer surface. The method further includes curing the dispensed material to convert the liquid mass into a solid encapsulant having an outer encapsulant surface. The curing step is performed under conditions to make the outer encapsulant surface undulating, e.g., with non-uniform surface features.

The curable material can alternatively be dispensed onto a first substrate that does not include an LED die, and later be affixed to an LED die or package as an encapsulant. Thus, after curing under conditions to convert the liquid mass to a solid film or mass with a self-formed undulating outer surface, the solid film or mass (referred to also as an encapsulant due to its ultimate use in connection with an LED) can then be affixed to a second substrate that does include an LED die. The second substrate may or may not include an initial encapsulating material around the LED die, and a transparent bonding material may be used to affix the solid film or mass into position, but in any case the solid film or mass that was formed on the first substrate forms the outermost portion of the final encapsulant structure for the LED package. The solid film or mass is sized appropriately for placement on the LED package, and in some cases can be separated from the first substrate (e.g. a release liner) before such placement.

These and other aspects of the present application will be apparent from the detailed description below. In no event, however, should the above summaries be construed as limitations on the claimed subject matter, which subject matter is defined solely by the attached claims, as may be amended during prosecution.

### BRIEF DESCRIPTION OF THE DRAWINGS

Throughout the specification, reference is made to the appended drawings, where like reference numerals designate like elements, and wherein:

FIG. 1a is a schematic cross-sectional view of an LED package including a substrate on which a liquid mass of curable material has been dispensed, and FIG. 1b is a view of same after a curing step that converts the liquid mass into a solid encapsulant having an undulating outer surface;

FIG. 2a is a schematic cross-sectional view of another LED package including a substrate on which a liquid mass of curable material has been dispensed, and FIG. 2b is a view of same after a curing step that converts the liquid mass into a solid encapsulant having an undulating outer surface;

FIGS. 3-4 are top view photomicrographs of LED packages in which the encapsulant has a self-formed undulating outer surface;

FIGS. 5, 7, and 9 are top view photomicrographs of LED packages in which the encapsulant has a self-formed undulating outer surface, the undulating surface of FIG. 7 having a very low frequency and amplitude;

FIGS. 6, 8, and 10 are top view photomicrographs of films suitable for use as an encapsulant in an LED package, each film having a self-formed undulating outer surface, the undulating surface of FIG. 8 having a particularly low frequency and amplitude;

FIGS. 11, 13, and 15 are top view photomicrographs of LED packages in which the encapsulant has a smooth outer surface; and

FIGS. 12, 14, and 16 are top view photomicrographs of films suitable for use as an encapsulant in or with an LED package, each film having a smooth outer surface.

### DETAILED DESCRIPTION OF THE ILLUSTRATIVE EMBODIMENTS

The encapsulant of a packaged LED has an outer surface that typically contacts air. Depending on the refractive index properties of the encapsulant and the LED die, and the geometry of the package, some light that is generated within the LED die and that is transmitted out of the LED die into the encapsulant can be reflected at the outer surface of the encapsulant and be directed back into the package, where it may be absorbed, thus detracting from the luminous output of the packaged LED. Providing the outer encapsulant surface with undulating surface features can decrease the probability that such light rays will be reflected back into the package. The undulating surface features can also be advantageous in applications where it is desirable to create a more evenly distributed diffuse light source than can be provided by a simple LED die alone.

In this regard, “light emitting diode” or “LED” refers to a diode that emits light, whether visible, ultraviolet, or infrared. This includes incoherent epoxy-encased semiconductor devices marketed as “LEDs”, whether of the conventional or super-radiant variety. Vertical cavity surface emitting laser diodes are another form of light emitting diode. Further, “LED die” refers to an LED in its most basic form, i.e., in the form of an individual component or chip made by semiconductor wafer processing procedures. The component or chip can include electrical contacts suitable for application of power to energize the device. The individual layers and other functional elements of the component or chip are typically formed on the wafer scale, the finished wafer finally being diced into individual piece parts to yield a multiplicity of LED dies.

Techniques are described herein for producing encapsulated LEDs, where the encapsulant has an undulating outer surface, without the need to etch, mold, machine, or otherwise modify the shape of a preformed solid encapsulant. Rather, techniques are disclosed for self-forming an undulating outer surface in the encapsulant while the encapsulant material is cured from a liquid state to a solid. Applicants have found that with proper selection of curable material and under appropriate curing conditions, an undulating outer surface can be self-formed in an encapsulant for use in or with LED packages.

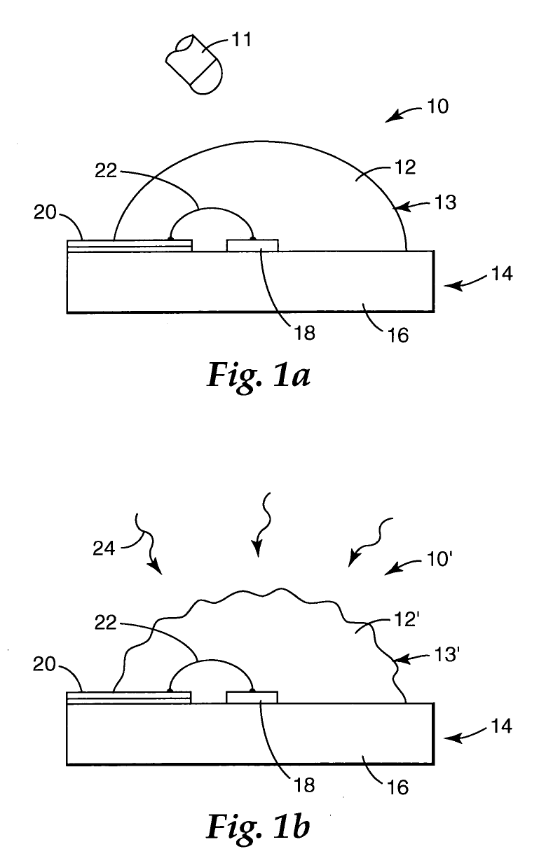

Turning now to FIG. 1a, an LED package 10 is shown, in which a curable material has been dispensed by a dispensing nozzle 11 to form a liquid mass 12 on a substrate 14. The liquid mass 12 has a shape determined to some extent by the density, viscosity, volume, and surface tension of the curable material, as well as by environmental conditions such as local gravity and temperature. Liquid mass 12 also has an outer surface 13 that is smooth, and unconstrained by any external body.

The substrate 14 includes a film, carrier, or header 16 on which an LED die 18 is mounted. LED die 18 generates light when an electrical current is applied through header 16 and another electrical contact 20, which electrical contact 20 is electrically insulated from header 16 and connects to the LED die 18 by a wire bond 22. The liquid mass 12 encapsulates the LED die and wire bond 22.

In FIG. 1b, the LED package is shown after exposure to radiation 24 of sufficient energy and suitable wavelength to cause full curing of the liquid mass 12. The LED package is substantially changed by this curing operation, and is thus labeled 10′. The encapsulating liquid mass 12 is also changed by the curing operation, but not only by changing to a solid encapsulant 12′. Beyond that, the smooth outer surface 13 of the liquid mass 12 has changed into an undulating outer surface 13′ of the solid encapsulant 12′, the undulating outer surface 13′ being characterized by a plurality of surface features-depressions and protuberances as shown in the figure. The surface features are typically non-uniform in size and shape. However, the amplitude of the surface features, measured e.g. from the top of a protuberance to the bottom of an adjacent depression, typically is in a range from about 0.01 to about 1.0 mm, or even from about 0.1 to about 0.5 mm. The width of the surface features, measured e.g. from the top of one protuberance to the nearest top of an adjacent protuberance, typically is in a range from about 0.01 to about 4 mm, or even from about 0.1 to about 2 mm. The solid encapsulant 12′ is electrically non-conductive.

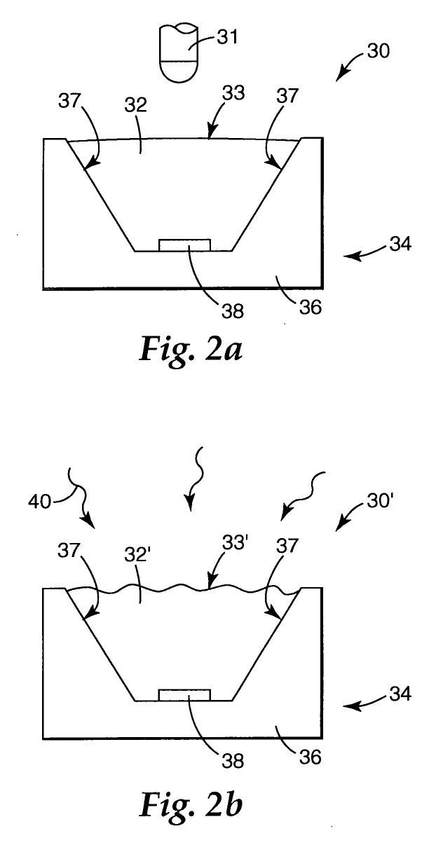

The method is depicted again in connection with FIGS. 2a and 2b. In FIG. 2a, an LED package 30 is shown, in which a curable material has been dispensed by a dispensing nozzle 31 to form a liquid mass 32 on a substrate 34. The liquid mass 32 has a shape determined to some extent by the density, viscosity, volume, and surface tension of the curable material, by the geometry of the substrate, as well as by environmental conditions such as local gravity and temperature. Liquid mass 32 also has an outer surface 33 that is smooth, and unconstrained by any external body.

The substrate 34 includes a carrier or header 36 having a reflective cup, at the bottom of which an LED die 38 is mounted. The header 36 includes inclined reflective surfaces 37 forming the cup. LED die 38 generates light when an electrical current is applied through electrical contacts, not shown. Electrical connections to the LED die can be made through the substrate, by wire bond(s) or, in the case of a flip-chip LED die configuration, by conductive strips connected to contact pads at the bottom of the LED die. The liquid mass 32 encapsulates the LED die and any wire bond(s).

In FIG. 2b, the LED package is shown after exposure to radiation 40 of sufficient energy and suitable wavelength to cause full curing of the liquid mass 32. The LED package is substantially changed by this curing operation, and is thus labeled 30′. The encapsulating liquid mass 32 is also changed by the curing operation, but not only by changing to a solid encapsulant 32′. Beyond that, the smooth outer surface 33 of the liquid mass 32 has changed into an undulating outer surface 33′ of the solid encapsulant 32′, the undulating outer surface 33′ being characterized by a plurality of surface features-depressions and protuberances as shown in the figure. The surface features are typically non-uniform in size and shape. However, the amplitude and width of the surface features are typically in the ranges described above.

Without wishing to be bound by theory, the formation of the undulating textured surface may be the result of differential rates of conversion of the liquid encapsulant resin as a function of depth. Such gradients of conversion in thick film samples are due to significant light absorption by the resin. See for example, Payne et al., Journal of Applied Polymer Science Vol. 66, 1267-1277 (1997) and Stolov et al., Polymer Engineering and Science, Vol. 41, No. 2, 314-328 (2001). More specifically, the surface of the (initially liquid) encapsulant may cure more rapidly than the remainder of the liquid mass, such that the surface solidifies to form a film or “skin” prior to the solidification of the bulk of the encapsulant resin underneath the surface film/skin. This phenomenon results in the surface film being deformed or distorted as the bulk of the resin underneath the surface film solidifies on curing, forming a wrinkled or undulating surface topography. The extent of this surface distortion depends on the degree to which the bulk encapsulant resin material shrinks on curing and the differential rates of surface film formation and bulk encapsulant solidification on curing. Those skilled in the art of photocuring will appreciate that the mechanism for the formation of the undulating surface is a result of the confluence of a combination of variables including, but not necessarily limited to, resin viscosity, molecular weight of the starting resin components, the number of reactive functional groups present in the resin components (which affects the critical point of conversion where solidification occurs), the composition of the resin (e.g., the presence of molecular components that absorb at the wavelength of the curing radiation), the degree of volume shrinkage the resin experiences on curing, the intensity and spectral power distribution of light used to initiate curing, the temperature of the sample during curing, and the rate of the curing reaction on exposure to the initiating radiation.

Others have observed lower measured stress in cured acrylic layers where gradient conversion as described above has been observed (Payne et al., Journal of Applied Polymer Science Vol. 66, 1267-1277 (1997)). Such a reduction of stress may be of significant benefit for encapsulated light emitting diodes, for example by decreasing the stress on any wire bonds attached to the chip, during curing and during thermally induced expansion while in use.

Generally, liquid resin compositions suitable for use in the disclosed methods include photocurable resins that absorb at the wavelength of light used for initiating the curing reaction and that shrink upon curing. Photocurable resins are those that can be cured upon exposure to actinic radiation. Additional liquid resin properties of interest are the resin viscosity, molecular weight of the resin components prior to cure (related to shrinkage), the number of reactive functional groups present in the resin components (also related to shrinkage as well as the rate of solidification), and the rate of the curing reaction. Examples of such liquid resin materials include, but are not limited to, resins that contain aliphatic unsaturation such as (meth)acrylate functional resins preferably containing at least some aromatic groups and photocurable silicon-containing materials, for example silicone resin formulations, at least one of the components of which contains aromatic groups, that can be cured for example by photohydrosilylation. Further details on suitable resin materials can be found in commonly assigned and copending U.S. application Ser. No. 10/993,460, “Method of Making Light Emitting Device With Silicon-Containing Encapsulant”, filed Nov. 18, 2004, which application is incorporated by reference herein to the extent it is not inconsistent with the present specification.

Useful wavelengths and intensities of light radiation used for curing include any that induce curing chemistry and are absorbed by some portion of the encapsulant resin. Significantly, the absorption of such radiation by the encapsulant resin produces a gradient in conversion as a function of depth through the resin layer. Useful light radiation in some cases is ultraviolet (UV) light, i.e., light whose wavelength is less than 400 nm, and in some cases UV light whose wavelength is less than 300 nm can be particularly beneficial.

In cases where the resin comprises (meth)acrylate functional materials, formation of an undulating outer encapsulant surface generally is promoted by excluding oxygen from the system during the curing process so as to avoid oxygen inhibition of the cure at the surface.

There are several variables that may have an effect on the amplitude, width, and overall pattern of the undulating features on the surface. Generally, resins that exhibit large differences in the rate of solidification between the surface and the bulk of the encapsulant and that exhibit a large amount of shrinkage may produce structures with a higher frequency or larger amplitude of undulations (narrower or deeper). Resins that exhibit less of a differential rate of solidification between the surface and the bulk, and/or that undergo little or no shrinkage during curing, may have lower frequency and/or shallower undulations.

As mentioned above, the disclosed methods for self-forming an undulating surface on an LED encapsulant do not require etching, molding, machining, or otherwise modifying the shape of a preformed solid encapsulant. Note, however, that the disclosed methods can if desired also include or be combined with known methods of forming non-smooth encapsulant surfaces. For example, after curing the liquid mass to form a solid encapsulant with an undulating outer surface, such outer surface can subsequently be etched or machined to add or subtract surface features to further modify the light scattering properties of the surface. As another example, microspheres or other particles can be incorporated into the curable material to impart further roughness or texture to the undulating surface of the cured solid encapsulant.

### EXAMPLES

Curable Formulation 1: To a small amberjar was added 9.5 g of acrylic acid 2-(naphthalen-2-ylsulfanyl)ethyl ester (prepared as described in co-assigned pending U.S. patent application Ser. No. 11/026,573, “High Refractive Index, Durable Hard Coats”, filed Dec. 30, 2004) and 0.5 g of trimethylolpropane triacrylate (TMTPA, trade name Sartomer SR-351, available from Sartomer Company, Inc., Exton, Pa.). The contents were thoroughly mixed using a vortex mixer. To the resin was added I percent by weight of the catalyst, Lucirin™ TPO-L, available from BASF Corp., Florham Park, N.J. The mixture was again mixed, degassed under vacuum, and stored under argon.

Curable Formulation 2: To a mixture of 5.00 g of vinyl terminated poly(phenylmethylsiloxane) PMV-9925 (available from Gelest, Inc., Morrisville, Pa.) and 1.92 g of hydride terminated poly(methylhydrosiloxane-co-phenylmethylsiloxane) HPM-502 (also available from Gelest, Inc.) was added 100 μL of a solution of 17.0 mg of [(CH₃)C₅H₄]Pt(CH₃)₃ (available from Strem Chemicals, Inc., Newburyport, Mass.) in 1.00 mL of CH₂Cl₂ (approximately 200 ppm of Pt).

Curable Formulation 3: To a mixture of 5.00 g of vinyl terminated poly(diphenylsiloxane-co-dimethylsiloxane) PDV-2331 (available from Gelest, Inc., Morrisville, Pa.) and 0.38 g of hydride terminated poly(methylhydrosiloxane-co-phenylmethylsiloxane) HPM-502 (also available from Gelest, Inc.) was added 100 μL of a solution of 17.0 mg of [(CH₃)C₅H₄]Pt(CH₃)₃ (available from Strem Chemicals, Inc., Newburyport, Mass.) in 1.00 mL of CH₂Cl₂ (approximately 200 ppm of Pt).

Curable Formulation 4: To a mixture of 5.00 g of vinyl terminated poly(diphenylsiloxane-co-dimethylsiloxane) PDV-2331 (available from Gelest, Inc., Morrisville, Pa.)) and 0.38 g of hydride terminated poly(methylhydrosiloxane-co-phenylmethylsiloxane) HPM-502 (also available from Gelest, Inc.) was added 100 μL of a solution of 21.0 mg of (CH₃COCHCOCH₃)₂Pt (available from Sigma Aldrich, Milwaukee, Wis.) in 1.00 mL of CH₂Cl₂ (approximately 200 ppm of Pt).

LED Measurement:

The light output from the LEDs for the examples below were measured before and after encapsulation using a spectroradiometer, designated OL 770-LED by Optronic Laboratories, Inc., Orlando, Fla., which was fitted with an integrating sphere designated OL IS-670-LED also by Optronic Laboratories, Inc. The spectroradiometer was calibrated to report the radiant energy entering the integrating sphere at the input port as a function of the wavelength of light. The software supplied with the spectroradiometer calculates optical characteristics such as total radiant flux and the radiant efficiency from the measured spectral data.

### Example 1a

### Self-Forming Macrostructured Encapsulant in an LED (Formulation 1)

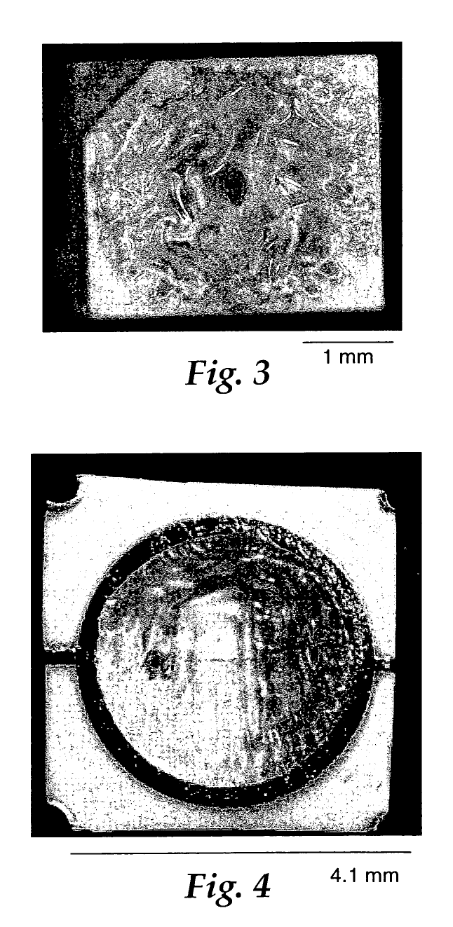

The Curable Formulation 1, which is a photocurable, high refractive index liquid resin, was used to encapsulate an LED. The LED was a blue-emitting Cree MB LED die mounted in a 1210 PLCC-style package or carrier. This carrier has a well or cavity in which the LED die is centrally mounted, and includes one wire bond attached to the top of the LED die. The well or cavity has a flat, circular bottom and vertical side-walls, the cavity being about 1 mm deep and about 2.4 mm in diameter. A syringe having a 22-gauge needle was used to fill this cavity to its top edge with a first mass of the liquid resin, thus encapsulating the LED die and a portion of the wire bond. The outer (upper) surface of the encapsulant was substantially flat and smooth, and was unconstrained by any external body. The encapsulant resin in the LED package was placed under a flowing argon atmosphere for approximately 15 minutes prior to irradiation and was cured in an oxygen-free environment to prevent oxygen inhibition of the curing reaction. The filled package was placed about 2 inches below two UV bulbs designated F15T8/350BL (Osram Sylvania, Danvers, Mass.) for about 20 minutes. After curing, a first solid encapsulating resin was formed, and its outer (upper) surface was concave, presumably as a result of shrinkage, but was otherwise smooth and regular. A second mass of the same liquid resin was then dispensed over the first solid encapsulant to build up the size of the encapsulant. The amount of liquid dispensed was sufficient to form a raised dome above the surface of the carrier. This second mass, which had a curved, substantially smooth and unconstrained outer surface, was cured in the same manner as before, i.e., argon purging of the encapsulant resin prior to curing and curing under exposure to two UV lamps designated F15T8/350BL for about 20 minutes. After the second curing step, the resulting LED package had a solid encapsulant composed of the solidified first mass of resin combined with the solidified second mass of resin. During the second curing step, however, the outer surface of the second mass of resin (and thus the outer surface of the overall solid encapsulant) became wrinkled and undulated, as shown in the top view photomicrograph of FIG. 3. As can be seen in the figure, the undulating surface features are non-uniform in shape and size. However, the width of the undulations was measured to be on the order of about 0.1 mm.

The light output of the LED, before and after encapsulation, was measured under constant current of approximately 20 milliamps. The emission of the LED package after encapsulation exhibited about a 70% increase relative to the unencapsulated LED package. Some fraction of this increase is due to increased light extraction from the LED die into the encapsulant. An additional fraction is due to increased extraction from the (2-layered) encapsulant into air due to the undulating surface of the encapsulant.

### Example 1b

### Self-Forming Macrostructured Encapsulant in an LED (Formulation 1)

The Curable Formulation 1, which is a photocurable, high refractive index liquid resin, was used to encapsulate an LED. The LED was a blue-emitting Cree XT LED die (Cree Part No. C460XT290-0119-A, Lot ID 064901 OSD) mounted in a Kyocera package or carrier (Kyocera Part No. KD-LA2707). This carrier has a well or cavity in which the LED die is mounted off-center, and includes one wire bond attached to the top of the LED die. The well or cavity has a flat, circular bottom which is gold plated and 45 degree side-walls which are silver plated, the cavity being about 0.6 mm deep and about 3.1 mm in diameter at the top of the cavity. A syringe having a 27-gauge needle was used to fill this cavity to its top edge with a mass of the liquid resin, thus encapsulating the LED die and the wire bond. The outer (upper) surface of the encapsulant was substantially flat and smooth, and was unconstrained by any external body. The encapsulant resin in the LED package was degassed under vacuum and backfilled with argon three times prior to use. The encapsulant resin in the LED package was cured in an oxygen-free environment to prevent oxygen inhibition of the curing reaction. The filled package was placed I cm below a hand-held TLC lamp (Spectroline, model ENF-204C, 0.20 amp, Spectronics Corporation, Westbury, N.Y.) emitting at 365 nm for about 15 minutes producing a solid encapsulant material. A measure of dose was not possible as the incident radiation was below the sensitivity level of the available dosimeter, a UV Power Puck made by Electronic Instrument and Technology, Inc., Sterling, Va. The outer surface of the solid encapsulant was wrinkled and undulated, as shown in the top view photomicrograph of FIG. 4. As can be seen in the figure, the undulating surface features are non-uniform in shape and size. However, the width of the undulations was measured to be on the order of about 0.1 mm.

The light output of the LED, before and after encapsulation, was measured under constant current of approximately 20 milliamps. The measured efficiency of emission from the unencapsulated LED package was 12.50%. The measured efficiency of emission of the LED package after encapsulation was 16.51%, i.e., an approximately 32% increase in efficiency relative to the unencapsulated LED package. Some fraction of this increase is due to increased light extraction from the LED die into the encapsulant. An additional fraction is due to increased extraction from the encapsulant into air due to the undulating surface of the encapsulant.

### Example 2a

### Self-Forming Macrostructured Encapsulant in an LED (Formulation 2)

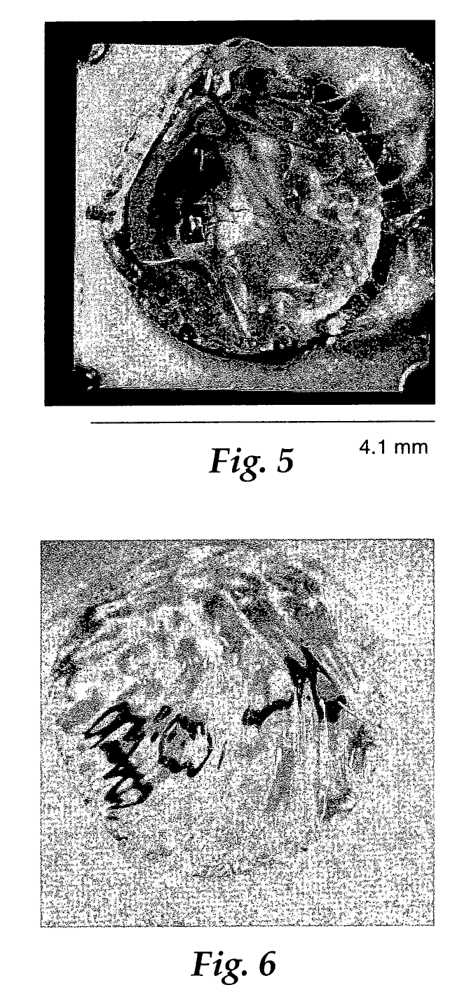

The Curable Formulation 2, which is a photocurable phenyl-containing siloxane liquid resin, was used to encapsulate an LED. The LED was a blue-emitting Cree XT LED die (Cree Part No. C460XT290-0119-A, Lot ID 064901 OSD) mounted in a Kyocera package or carrier (Kyocera Part No. KD-LA2707). This carrier has a well or cavity in which the LED die is mounted off-center, and includes one wire bond attached to the top of the LED die. The well or cavity has a flat, circular bottom which is gold plated and 45 degree side-walls which are silver plated, the cavity being about 0.6 mm deep and about 3.1 mm in diameter at the top of the cavity. A syringe having a 27-gauge needle was used to fill this cavity to its top edge with a mass of the liquid resin, thus encapsulating the LED die and the wire bond. The outer (upper) surface of the encapsulant was substantially flat and smooth, and was unconstrained by any external body. The resin formed a liquid mass that appeared flat relative to the surface of the carrier and filled the cavity of the carrier. The liquid mass was placed under a hand-held UV lamp (Mineralight Lamp, model UVG-11, 254 nm, 0.16 amp, available from UVP, Inc., Upland, Calif.) for 15 minutes. The dose was measured to be about 137 mJ/cm² of UVC per 2 minutes using a UV Power Puck (Electronic Instrument and Technology, Inc., Sterling, Va.). The UV exposure was effective to cure the liquid encapsulant, converting it to a solid encapsulant, having an outer encapsulant surface, the surface exhibiting highly undulating surface features similar to those of Example 1b. A photomicrograph of the cured encapsulant in the LED can be seen in FIG. 5.

The light output of the LED, before and after encapsulation, was measured under constant current of approximately 20 milliamps. The measured efficiency of emission from the unencapsulated LED package was 12.48%. The measured efficiency of emission of the LED package after encapsulation was 19.06%, i.e., approximately a 53% increase in efficiency relative to the unencapsulated LED package. Some fraction of this increase is due to increased light extraction from the LED die into the encapsulant. An additional fraction is due to increased extraction from the encapsulant into air due to the undulating surface of the encapsulant.

### Example 2b

### Self-Forming Macrostructured Film (Formulation 2)

The Curable Formulation 2, which is a photocurable phenyl-containing siloxane liquid resin, was dispensed from a syringe onto a glass slide. The outer (upper) surface of the film had a slight curvature and was smooth. The film was unconstrained by any external body either from the sides or on the top of the film. The liquid film was placed under a hand-held UV lamp (Mineralight Lamp, model UVG-11, 254 nm, 0.16 amp, available from UVP, Inc., Upland, Calif.) for 15 minutes. The UV exposure was effective to cure the liquid encapsulant, converting it to a solid encapsulant having an outer surface, the surface exhibiting a degree of highly undulating surface features similar to those in Example 2a. A photomicrograph of the cured film can be seen in FIG. 6. The numbers seen in the photomicrograph are displayed underneath the film and are present for the purpose of visualizing the surface features of the film. This example demonstrates that the composition is effective for encapsulating light emitting diodes disposed on a flat substrate without lateral confinement, such as a flexible polymer circuit film, where the encapsulant has a self-formed undulating surface. Alternatively, the cured undulating film can be formed on an LED-sized film substrate (e.g. a small disk or an array of such disks), or a multitude of small LED-sized disks of the undulating film/film substrate combination can be punched out of a larger coated film, or the cured undulating film can be formed on a release liner and then separated therefrom and affixed to the surface of an LED or partially encapsulated LED package to yield an LED package with an enhanced light extraction encapsulant.

### Example 3a

### Self-Forming Macrostructured Encapsulant in an LED (Formulation 3)

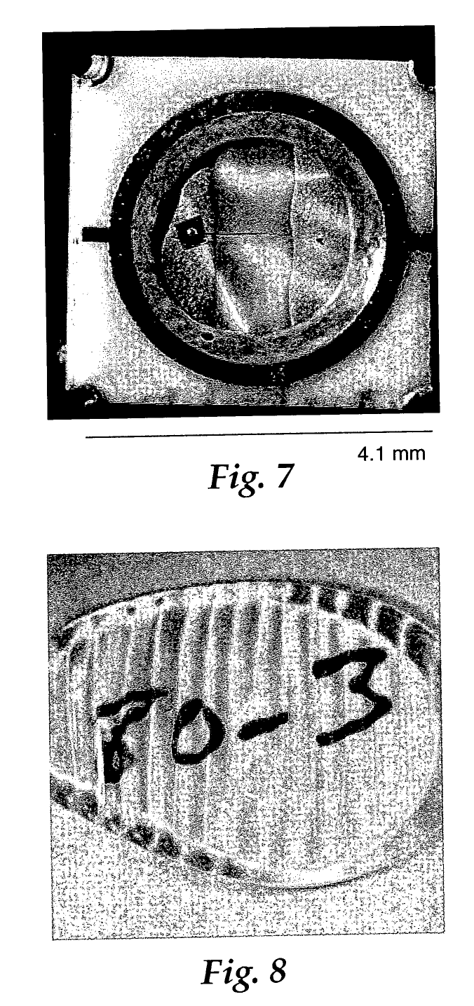

The Curable Formulation 3, a phenyl-containing siloxane resin having a higher viscosity and containing a higher molecular weight siloxane polymer than Curable Formulation 2, was dispensed from the tip of a 27-gauge needle into a ceramic Kyocera package similar to the one described in Example 2a. The resin formed a liquid mass that filled the cavity such that the surface of the encapsulant was substantially flat with respect to the surface of the ceramic package. The liquid mass had a smooth unconstrained outer surface, and was placed under a hand-held UV lamp (Mineralight Lamp, model UVG-11, 254 nm, 0.16 amp, available from UVP, Inc., Upland, Calif.) for 15 minutes. The dose was measured to be about 137 mJ/cm² of UVC per 2 minutes using a UV Power Puck (Electronic Instrument and Technology, Inc., Sterling, Va.). The UV exposure was effective to cure the liquid encapsulant, converting it to a solid encapsulant, having an outer encapsulant surface, the surface exhibiting a degree of undulating surface features. The undulations in the solid encapsulant surfaces of this Example 3a, however, were of a lower frequency (i.e., of greater width) than the undulations observed in Example 2a. A photomicrograph of the cured encapsulant in the LED can be seen in FIG. 7.

The light output of the LED, before and after encapsulation, was measured under constant current of approximately 20 milliamps. The measured efficiency of emission from the unencapsulated LED package was 12.68%. The measured efficiency of emission of the LED package after encapsulation was 16.34%, i.e., approximately a 29% increase in efficiency relative to the unencapsulated LED package. Some fraction of this increase is due to increased light extraction from the LED die into the encapsulant. An additional fraction is due to increased extraction from the encapsulant into air due to the undulating surface of the encapsulant.

### Example 3b

### Self-Forming Macrostructured Film (Formulation 3)

The Curable Formulation 3, which is a photocurable phenyl-containing siloxane liquid resin, was dispensed from a syringe onto a glass slide. The outer (upper) surface of the film had a slight curvature and was smooth. The film was unconstrained by any external body either from the sides or on the top of the film. The liquid film was placed under a hand-held UV lamp (Mineralight Lamp, model UVG-11, 254 nm, 0.16 amp, available from UVP, Inc., Upland, Calif.) for 15 minutes. The UV exposure was effective to cure the liquid encapsulant, converting it to a solid encapsulant, having an outer surface, the surface exhibiting a degree of undulating surface features. A photomicrograph of the cured film can be seen in FIG. 8. The undulations in the solid encapsulant surfaces of this Example 3b, however, were of a lower frequency (i.e., of greater width) than the undulations observed in Example 2b. The numbers seen in the photomicrograph are displayed underneath the film and are present for the purpose of visualizing the surface features of the film. This example demonstrates that the composition is effective for encapsulating light emitting diodes disposed on a flat substrate without lateral confinement, such as a flexible polymer circuit film, where the encpasulant has a self-formed undulating surface. Alternatively, the undulating film can be produced on a film substrate or on a release liner and then affixed to an LED or LED package as described above to produce an LED encapsulant with enhanced light extraction. This example also demonstrates that the undulating surface features can be produced in a substantially regular pattern.

### Example 4a

### Self-Forming Macrostructured Encapsulant in an LED (Formulation 4)

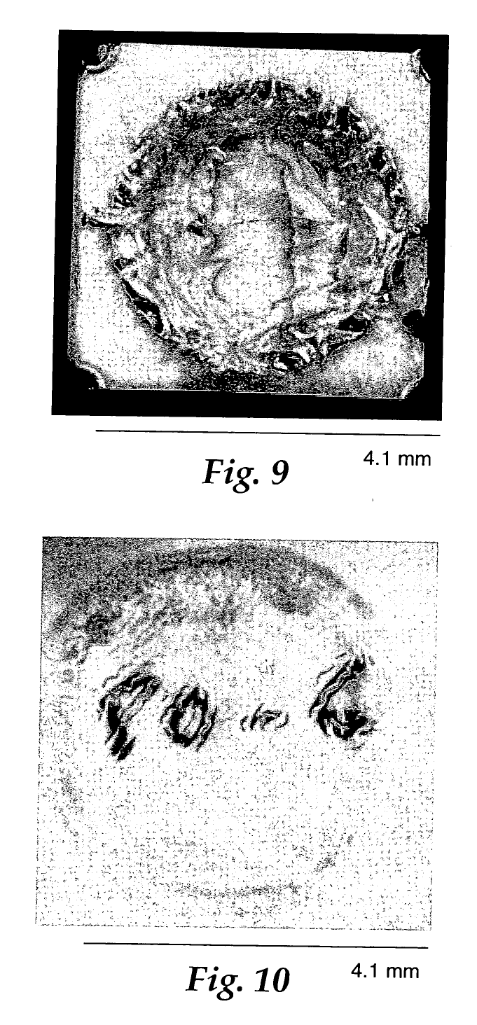

The Curable Formulation 4, a phenyl-containing siloxane resin of the same composition as formulation 3, but containing a different platinum catalyst, was dispensed from the tip of a 27-gauge needle into a ceramic Kyocera package similar to the one described in Example 2a. The resin formed a liquid mass that filled the cavity such that the surface of the encapsulant was substantially flat with respect to the surface of the ceramic package. The liquid mass had a smooth unconstrained outer surface, and was placed under a hand-held UV lamp (Mineralight Lamp, model UVG-11, 254 nm, 0.16 amp, available from UVP, Inc., Upland, Calif.) for 15 minutes. The dose was measured to be about 137 mJ/cm² of UVC per 2 minutes using a UV Power Puck (Electronic Instrument and Technology, Inc., Sterling, Va.). The UV exposure was effective to cure the liquid encapsulant, converting it to a solid encapsulant, having an outer encapsulant surface, the surface exhibiting a degree of highly undulating surface features. The undulations in the solid encapsulant surfaces of this Example 4a, however, were of a higher frequency than the undulations observed in Example 3a. A photomicrograph of the cured encapsulant in the LED can be seen in FIG. 9.

The light output of the LED, before and after encapsulation, was measured under constant current of approximately 20 milliamps. The measured efficiency of emission from the unencapsulated LED package was 13.14%. The measured efficiency of emission of the LED package after encapsulation was 17.47%, i.e., approximately a 33% increase in efficiency relative to the unencapsulated LED package. Some fraction of this increase is due to increased light extraction from the LED die into the encapsulant. An additional fraction is due to increased extraction from the encapsulant into air due to the undulating surface of the encapsulant.

### Example 4b

### Self-Forming Macrostructured Film (Formulation 4)

The Curable Formulation 4, which is a photocurable phenyl-containing siloxane liquid resin, was dispensed from a syringe onto a glass slide. The outer (upper) surface of the film had a slight curvature and was smooth. The film was unconstrained by any external body either from the sides or top of the film. The liquid film was placed under a hand-held UV lamp (Mineralight Lamp, model UVG-11, 254 nm, 0.16 amp, available from UVP, Inc., Upland, Calif.) for 15 minutes. The UV exposure was effective to cure the liquid encapsulant, converting it to a solid encapsulant, having an outer surface, the surface exhibiting a degree of undulating surface features. A photomicrograph of the cured film can be seen in FIG. 10. The undulations in the solid encapsulant surfaces of this Example 4b, however, were of a higher frequency than the undulations observed in Example 3b. The numbers seen in the photomicrograph are displayed underneath the film and are present for the purpose of visualizing the surface features of the film. This example demonstrates that the composition is effective for encapsulating light emitting diodes disposed on a flat substrate without lateral confinement, such as a flexible polymer circuit film, where the encapsulant has a self-formed undulating surface. Alternatively, the undulating film can be produced on a film substrate or on a release liner and then affixed to an LED or LED package as described above to produce an LED encapsulant with enhanced light extraction.

### Comparative Example 1a

### Smooth Surface Encapsulant in an LED (Formulation 2)

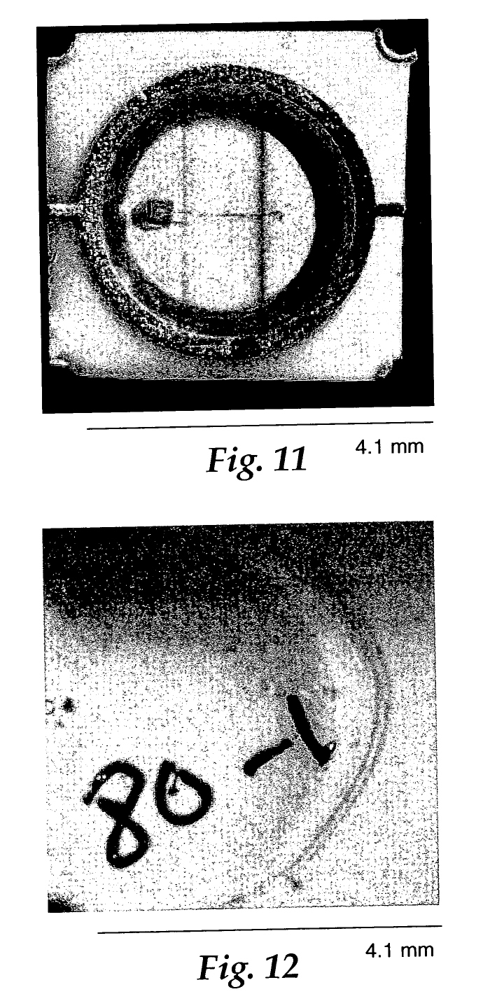

The Curable Formulation 2, which is a photocurable phenyl-containing siloxane liquid resin, was used to encapsulate an LED. The LED was a blue-emitting Cree XT LED die (Cree Part No. C460XT290-0119-A, Lot ID 0649010SD) mounted in a Kyocera package or carrier (Kyocera Part No. KD-LA2707). This carrier has a well or cavity in which the LED die is mounted off-center, and includes one wire bond attached to the top of the LED die. The well or cavity has a flat, circular bottom which is gold plated and 45 degree side-walls which are silver plated, the cavity being about 0.6 mm deep and about 3.1 mm in diameter at the top of the cavity. A syringe having a 27-gauge needle was used to fill this cavity to its top edge with a mass of the liquid resin, thus encapsulating the LED die and the wire bond. The outer (upper) surface of the encapsulant was substantially flat and smooth, and was unconstrained by any external body. The resin formed a liquid mass that appeared flat relative to the surface of the carrier and filled the cavity of the carrier. The liquid mass was placed under a hand-held TLC lamp emitting at 365 nm (Spectroline, model ENF-204C, 0.20 amp, available from Spectronics Corporation, Westbury, N.Y.) for 15 minutes. A measure of dose was not possible as the incident radiation was below the sensitivity level of the UV Power Puck (Electronic Instrument and Technology, Inc., Sterling, Va.). The UV exposure was effective to cure the liquid encapsulant, converting it to a solid encapsulant, having a smooth outer encapsulant surface. A photomicrograph of the cured encapsulant in the LED can be seen in FIG. 11.

The light output of the LED, before and after encapsulation, was measured under constant current of approximately 20 milliamps. The measured efficiency of emission from the unencapsulated LED package was 12.09%. The measured efficiency of emission of the LED package after encapsulation was 14.32%, i.e., approximately an 18% increase in efficiency relative to the unencapsulated LED package. This increase is due to increased light extraction from the LED die into the encapsulant.

### Comparative Example 1b

### Film with Smooth Surface (Formulation 2)

The Curable Formulation 2, which is a photocurable phenyl-containing siloxane liquid resin, was dispensed from a syringe onto a glass slide. The outer (upper) surface of the film had a slight curvature and was smooth. The film was unconstrained by any external body either from the sides or on the top of the film. The liquid film was placed under a hand-held TLC lamp emitting at 365 nm (Spectroline, model ENF-204C, 0.20 amp, available from Spectronics Corporation, Westbury, N.Y.) for 15 minutes. The UV exposure was effective to cure the liquid encapsulant, converting it to a solid encapsulant, having a smooth outer surface. A photomicrograph of the cured film can be seen in FIG. 12. The numbers seen in the photomicrograph are displayed underneath the film and are present for the purpose of visualizing the lack of surface features in the film.

### Comparative Example 2a

### Smooth Surface Encapsulant in an LED (Formulation 3)

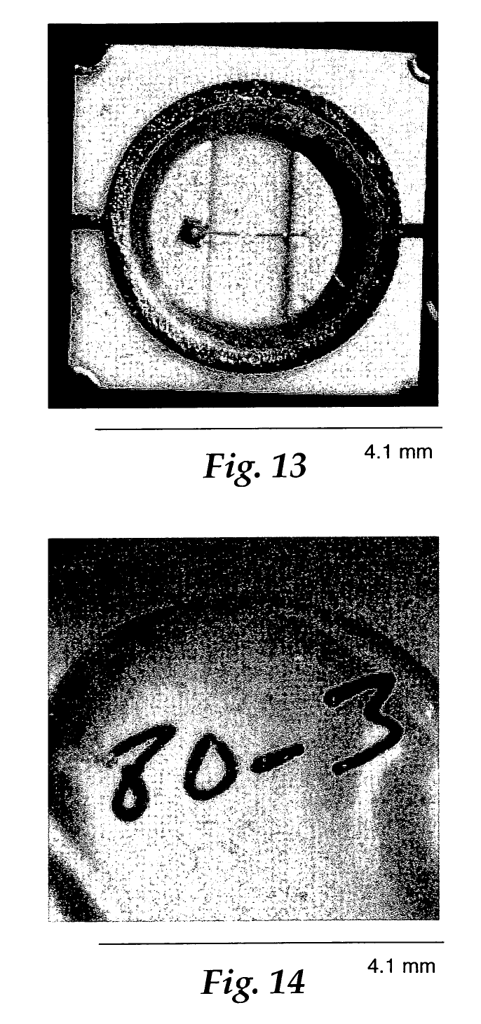

The Curable Formulation 3, a phenyl-containing siloxane resin having a higher viscosity and higher molecular weight than curable formulation 2, was dispensed from the tip of a 27-gauge needle into a ceramic Kyocera package similar to the one described in Example 2a. The resin formed a liquid mass that filled the cavity such that the surface of the encapsulant was substantially flat with respect to the surface of the ceramic package. The liquid mass had a smooth unconstrained outer surface, and was placed under a hand-held TLC lamp emitting at 365 nm (Spectroline, model ENF-204C, 0.20 amp, available from Spectronics Corporation, Westbury, N.Y.) for 15 minutes. A measure of dose was not possible as the incident radiation was below the sensitivity level of the UV Power Puck (Electronic Instrument and Technology, Inc., Sterling, Va.). The UV exposure was effective to cure the liquid encapsulant, converting it to a solid encapsulant, having a smooth outer encapsulant surface. A photomicrograph of the cured encapsulant in the LED can be seen in FIG. 13.

The light output of the LED, before and after encapsulation, was measured under constant current of approximately 20 milliamps. The measured efficiency of emission from the unencapsulated LED package was 12.54%. The measured efficiency of emission of the LED package after encapsulation was 14.72%, i.e., approximately a 17% increase in efficiency relative to the unencapsulated LED package. This increase is due to increased light extraction from the LED die into the encapsulant.

### Comparative Example 2b

### Film with Smooth Surface (Formulation 3)

The Curable Formulation 3, which is a photocurable phenyl-containing siloxane liquid resin, was dispensed from a syringe onto a glass slide. The outer (upper) surface of the film had a slight curvature and was smooth. The film was unconstrained by any external body either from the sides or on the top of the film. The liquid film was placed under a hand-held TLC lamp emitting at 365 nm (Spectroline, model ENF-204C, 0.20 amp, available from Spectronics Corporation, Westbury, N.Y.) for 15 minutes. The UV exposure was effective to cure the liquid encapsulant, converting it to a solid encapsulant, having a smooth outer surface. A photomicrograph of the cured film can be seen in FIG. 14. The numbers seen in the photomicrograph are displayed underneath the film and are present for the purpose of visualizing the lack of surface features in the film.

### Comparative Example 3a

### Smooth Surface Encapsulant in an LED (Formulation 4)

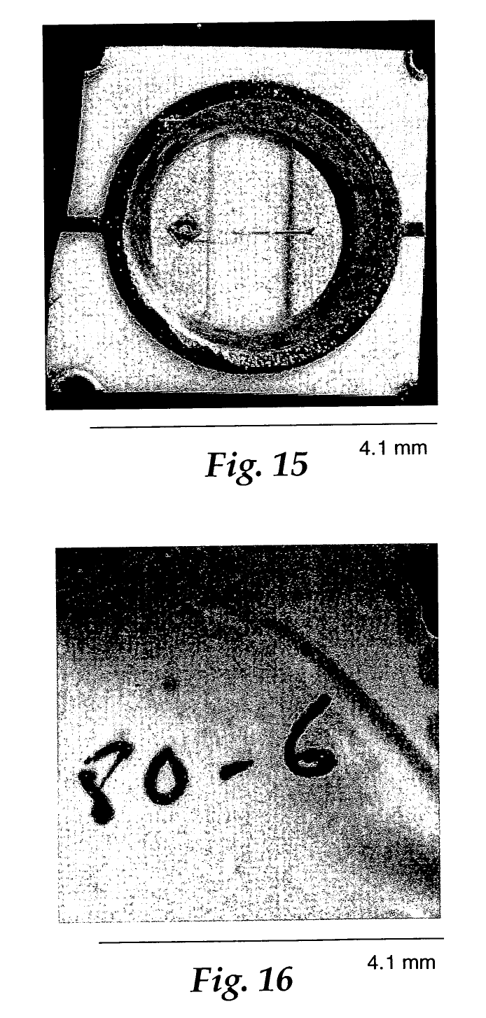

The Curable Formulation 4, a phenyl-containing siloxane resin of the same composition as Curable Formulation 3, but containing a different platinum catalyst, was dispense from the tip of a 27-gauge needle into a ceramic Kyocera package similar to the one described in Example 2a. The resin formed a liquid mass that filled the cavity such that the surface of the encapsulant was substantially flat with respect to the surface of the ceramic package. The liquid mass had a smooth unconstrained outer surface, and was placed under a hand-held TLC lamp emitting at 365 nm (Spectroline, model ENF-204C, 0.20 amp, available from Spectronics Corporation, Westbury, N.Y.) for 15 minutes. A measure of dose was not possible as the incident radiation was below the sensitivity level of the UV Power Puck (Electronic Instrument and Technology, Inc., Sterling, Va.). The UV exposure was effective to cure the liquid encapsulant, converting it to a solid encapsulant, having a smooth outer encapsulant surface. A photomicrograph of the cured encapsulant in the LED can be seen in FIG. 15.

The light output of the LED, before and after encapsulation, was measured under constant current of approximately 20 milliamps. The measured efficiency of emission from the unencapsulated LED package was 11.95%. The measured efficiency of emission of the LED package after encapsulation was 14.87%, i.e., approximately a 24% increase in efficiency relative to the unencapsulated LED package. This increase is due to increased light extraction from the LED die into the encapsulant.

### Comparative Example 3b

### Film with Smooth Surface (Formulation 4)

The Curable Formulation 4, which is a photocurable phenyl-containing siloxane liquid resin, was dispensed from a syringe onto a glass slide. The outer (upper) surface of the film had a slight curvature and was smooth. The film was unconstrained by any external body either from the sides or top of the film. The liquid film was placed under a hand-held TLC lamp emitting at 365 nm (Spectroline, model ENF-204C, 0.20 amp, available from Spectronics Corporation, Westbury, N.Y.) for 15 minutes. The UV exposure was effective to cure the liquid encapsulant, converting it to a solid encapsulant, having a smooth outer surface. A photomicrograph of the cured film can be seen in FIG. 16. The numbers seen in the photomicrograph are displayed underneath the film and are present for the purpose of visualizing the lack of surface features in the film.

The following table summarizes the measured efficiency increases of phenyl-siloxane encapsulated LEDs from Examples 2a, 3a, and 4a and Comparative Examples 1a, 2a, and 3a above, illustrating the higher efficiencies resulting from the self-formed undulating surface of the encapsulant. The reported percentages are the percent increase of the emission efficiency of the encapsulated LED relative to the emission efficiency of the unencapsulated LED.

| | Self-formed Undulating | Smooth Surface |
|---|---|---|
| | Surface Examples | Comparative Examples |
| Curable Formulation 2 | 53% | 18% |
| Curable Formulation 3 | 29% | 17% |
| Curable Formulation 4 | 33% | 24% |

Various modifications and alterations of the invention will be apparent to those skilled in the art without departing from the spirit and scope of the invention. It should be understood that the invention is not limited to illustrative embodiments set forth herein. All U.S. patents, patent application publications, and other patent and non-patent documents referred to herein are incorporated by reference, to the extent they are not inconsistent with the foregoing disclosure.

Furthermore, unless otherwise indicated, all numbers expressing feature sizes, amounts, and physical properties used in the specification and claims are to be understood as being modified by the term “about.” Accordingly, unless indicated to the contrary, the numerical parameters set forth in the present specification and claims are approximations that can vary depending upon the desired properties sought to be obtained by those skilled in the art utilizing the teachings disclosed herein.

What is claimed is:

1. A method of making an encapsulant suitable for use with an LED, the method comprising:
providing a substrate;
dispensing a first curable material onto the substrate to form thereon a first liquid mass of the first curable material, the first liquid mass having an unconstrained smooth outer surface; and
curing the dispensed material to convert the first liquid mass into a first solid encapsulant, the encapsulant having an outer encapsulant surface;
wherein the curing is performed under conditions to provide the outer encapsulant surface with undulating surface features.

2. The method of claim 1, wherein the curing step comprises exposing the first curable material to ultraviolet light having a wavelength less than 400 nm.

3. The method of claim 2, wherein the curing step comprises exposing the first curable material to ultraviolet light having a wavelength less than 300 nm.

4. The method of claim 1, wherein the substrate includes an LED die.

5. The method of claim 4, wherein the dispensing step dispenses the first curable material to encapsulate the LED die.

6. The method of claim 4, wherein the substrate also includes a wire bond connected to the LED die, and the dispensing step dispenses the first curable material to encapsulate the LED die and the wire bond.

7. The method of claim 4, wherein the substrate also includes a reflective cup in which the LED die is positioned, and wherein the dispensing step dispenses the first curable material into the reflective cup.

8. The method of claim 1, wherein the substrate includes a release liner.

9. The method of claim 8, further comprising:
removing the first solid encapsulant from the release liner and affixing the first solid encapsulant to an LED or LED package.

10. The method of claim 1, wherein the substrate comprises a film, the method further comprising:
affixing at least a portion of the film and the first solid mass to an LED or LED package.

11. The method of claim 1, wherein the substrate includes a second solid encapsulant, and the dispensing step dispenses the first curable material onto the second solid encapsulant.

12. The method of claim 11, wherein the first and second solid encapsulants comprise first and second light transmissive materials respectively, and the first light transmissive material is substantially the same as the second light transmissive material.

13. The method of claim 1, wherein the undulating surface features have a substantially regular pattern.

14. The method of claim 1, wherein the undulating surface features have widths of at least 0.01 millimeters.

15. The method of claim 1, wherein the first curable material is or comprises a photocurable resin formulation.

16. The method of claim 15, wherein the photocurable resin formulation contains aliphatic unsaturation.

17. The method of claim 16, wherein the photocurable resin formulation comprises acrylate and/or methacrylate groups.

18. The method of claim 16, wherein the photocurable resin formulation comprises silicon-bonded hydrogen functionality.

19. The method of claim 18, wherein the photocurable resin formulation comprises an organosiloxane.
